(19) United States
(12) Patent Application Publication
(10) Pub. No.: US 2006/0071351 A1
(43) Pub. Date: Apr. 6, 2006

(54) Mold compound interlocking feature to improve semiconductor package strength

(75) Inventor: Bernhard P. Lange, Garland, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 10/952,342

(22) Filed: Sep. 28, 2004

(51) Int. Cl. H01L 23/28

(52) U.S. Cl. 257/787

(57) ABSTRACT

A semiconductor package comprising a chip, a die pad adjacent the chip, said die pad having a side facing away from the chip, a portion of said side separated from an adjacent package surface by a distance greater than zero. The package further comprises mold compound abutting the chip and the die pad, wherein the distance between said portion and said adjacent package surface varies.

### BACKGROUND

Integrated circuits are fabricated on the surface of a semiconductor wafer in layers and later singulated into individual semiconductor devices, or “dies.” Since the material of a semiconductor wafer—commonly silicon—tends to be relatively fragile and brittle, a die (also called a “chip”) is often encapsulated in a protective housing or “package” to permit subsequent handling of the die such as for mounting on a circuit board. Among other things, the package may comprise a mold compound that is used to protect package components and to keep the components from slipping out of place.

As technology continues to improve, packages continue to decrease in size. Such a decrease in package size is desirable in terms of functionality and space efficiency. However, all else being equal, a decrease in package size also causes a package to become fragile. Specifically, in some cases, such packages of decreased size may comprise a mold compound that is not thick enough to adequately protect a component (e.g., a chip) in the package. In these cases, various stresses applied to the package may cause such a thin mold compound to crack or become otherwise damaged. In turn, such a crack in the mold compound may cause the die pad, a chip adjacent the die pad, bond wires coupled to the chip, or any other package components to loosen (i.e., delaminate) and fall out of place. In such cases, the package may become damaged or even be rendered useless.

FIG. 1a shows a cross-sectional side view of an exposed-die style package 100 (e.g., PowerPad® package, where an underside 150 of the package 100 is exposed) having a stamped leadframe 98. The package 100 comprises a die pad 102 and a chip 106 with an adhesive 104 situated therebetween. The chip 106 is coupled to lead fingers 108 and to the die pad 102 using bond wires. The package 100 is filled with a mold compound 112 that abuts package components, thereby holding the components securely in place. As packages continue to decrease in thickness (e.g., the die pad 102 decreases in thickness), the thickness of mold compound 112 between surfaces 114 (also called “underside”) of the die pad 102 and a surface 116 of the package 100 (also known as a surface of the mold compound 112) also continues to decrease. Such a decrease in the thickness of mold compound 112 weakens the mold compound 112 and eventually causes cracks 118 to form. A detailed view of such a crack 118 is shown in FIG. 1b. These cracks 118 may cause some or all components of the package 100 to fall out of place and become damaged or useless.

### SUMMARY

The problems noted above are solved in large part by a mold compound interlocking feature that improves semiconductor package strength. One exemplary embodiment may be a semiconductor package comprising a chip, a die pad adjacent the chip, said die pad having a side facing away from the chip, a portion of said side separated from an adjacent package surface by a distance greater than zero. The package further comprises mold compound abutting the chip and the die pad, wherein the distance between said portion and said adjacent package surface varies.

Another embodiment may comprise a method of preventing semiconductor die pad delamination comprising forming a die pad to be mated to a package surface, said die formed to have a die pad surface, the entirety of which is not parallel to the package surface. The method may further comprise mating said die pad to the package surface, wherein the distance between said die pad surface and said package surface is non-zero and varies across at least a portion of said die pad and injecting mold compound into said package.

### BRIEF DESCRIPTION OF THE DRAWINGS

For a detailed description of exemplary embodiments of the invention, reference will now be made to the accompanying drawings in which:

FIG. 1a shows a cross-sectional side view of a package with mold compound cracks;

FIG. 1b shows a detailed view of a mold compound crack;

FIG. 2 shows a cross-sectional side view of a package comprising a die pad having a stamped step-wise formation in accordance with various embodiments of the invention;

FIG. 3 shows a cross-sectional side view of a package comprising a die pad having an etched step-wise formation in accordance with embodiments of the invention; and

FIG. 4 shows a cross-sectional side view of a package comprising a die pad having a curvilinear formation in accordance with some embodiments of the invention.

### NOTATION AND NOMENCLATURE

Certain terms are used throughout the following description and claims to refer to particular system components. As one skilled in the art will appreciate, companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . .” Also, the term “couple” or “couples” is intended to mean either an indirect or direct electrical connection. Thus, if a first device couples to a second device, that connection may be through a direct electrical connection, or through an indirect electrical connection via other devices and connections.

### DETAILED DESCRIPTION

The following discussion is directed to various embodiments of the invention. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

Disclosed herein is a die pad feature that increases the strength of a package mold compound, thereby increasing the strength of the package and reducing or eliminating the likelihood of package damage caused by cracks in the mold compound. In general, a die pad in accordance with the preferred embodiment has a side generally adjacent a package surface. At least a portion of the die pad side is separated from the package surface by a distance (i.e., a distance greater than zero). Preferably, the non-zero distance varies. As will be explained below, in some embodiments, a die pad underside is formed (e.g., stamped or etched) in a step-wise pattern such that the mold compound thickness between a portion of the die pad underside and a package surface (i.e., mold compound surface) facing the die pad underside is greater than otherwise would be the case without a step-wise pattern. Because mold compound thickness between the die pad and the surface of the package is increased, the mold compound is strengthened and is relatively less likely to crack, compared to die pads without such step-wise formations. In other embodiments, non-planar (e.g., curvilinear) and sloped formations may be used instead of the aforementioned step-wise patterns. In each case, whether a step-wise pattern, curvilinear pattern or sloped pattern is used, the amount of mold compound abutting the outer edges of the die pad is maximized. The amount of mold compound abutting the die pad gradually decreases as the center of the die pad is approached. For these two reasons, the mold compound strength and overall package strength are substantially enhanced in comparison to currently used mold compounds and packages.

FIG. 2 shows a package 200 comprising a die pad 202 adjacent a chip 206 with an adhesive 204 fixed therebetween. The chip 206 is coupled with lead fingers 208 and the die pad 202 of a stamped lead frame 198 using bond wires 210. The package 200 is filled with a mold compound 212 (e.g., epoxy) that is used to hold components of the package 200 in place, such as to prevent the bond wires 210 from short circuiting by coming into electrical contact with each other. Outer edges 284 of the underside 250 of the die pad 202 are formed in a step-wise pattern, as shown. The step-wise pattern of the underside 250 is formed during a stamping process used to fabricate the lead frame 198. Although only two steps 280, 282 are shown in the step-wise patterns on each side of the die pad 202, any number of steps may be stamped into the die pad 202. In at least some embodiments, each of the steps in the step-wise patterns may be of substantially equal size. For example, the steps may be of substantially equal dimensions and/or spacing.

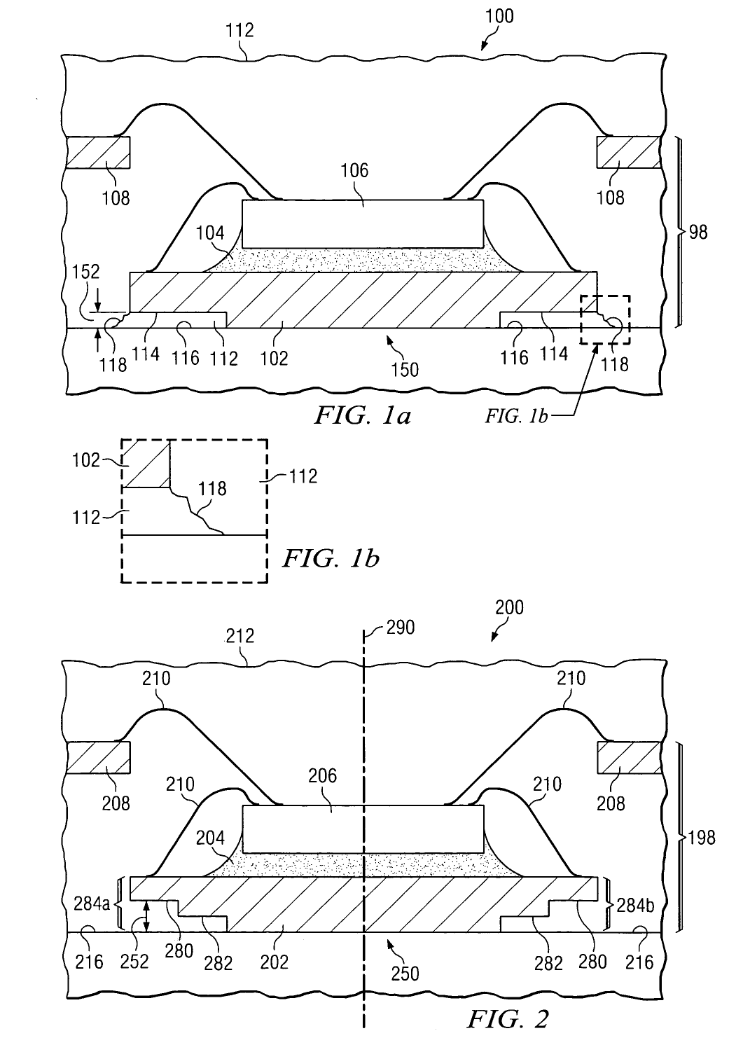

In contrast to FIG. 1a, the underside 250 of the die pad 202 has an outer edge 284a with a step 280 that is substantially further away from a surface 216 of the package 200 (i.e., surface of the mold compound 212), as indicated by arrow 252, than the distance between step 282 and surface 216 (the latter distance may be approximately the same as the distance 152 in FIG. 1a). Specifically, the distance between the surface 216 and the step 280 indicated by arrow 252 in FIG. 2 is greater than the distance between surface 116 and surface 114 indicated by arrow 152 in FIG. 1a. As such, there exists a relatively greater amount of mold compound 212 between the surface 216 and the step 280 in the embodiment of FIG. 2 relative to FIG. 1a. For this reason, the mold compound 212 fixed between the surface 216 and the step 280 is firmer and stronger than the mold compound 112 fixed between the surface 114 and 116. Because the mold compound 212 is stronger, the mold compound 212 is less likely to crack, thereby protecting the components of the package 200 from slipping out of place or becoming otherwise damaged. The distance indicated by arrow 252 may be application-specific and/or package-specific. Also, because the amount of mold compound 212 between the die pad 202 and the outer surface 216 of the package 200 is decreased gradually as a center 290 of the die pad 202 is approached, the die pad 202 is provided with better mechanical support compared to the die pad 102 of FIG. 1a. For this reason, package strength is increased and the package 200 is less likely to suffer damage. A similar structure may be found on any portion of the package 200, such as an outer edge 284b.

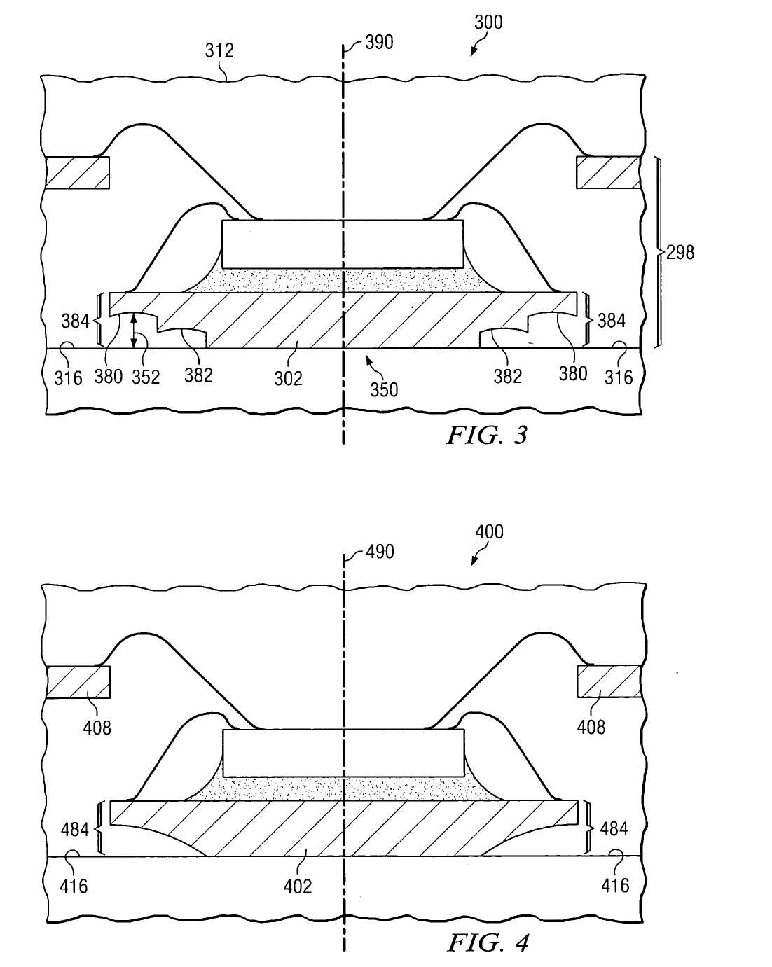

FIG. 3 shows a package 300 that is similar in some regards to the package 200 of FIG. 2, but in FIG. 3, the steps 380, 382 are curvilinear/curved. Whereas the step-wise patterns of the die pad 202 of FIG. 2 are formed using a stamping process, the step-wise patterns on outer edges 384 of a die pad 302 of FIG. 3 are formed using an etching process. Specifically, the step-wise patterns on the outer edges 384 of an underside 350 of the die pad 302 are formed during an etching process used to fabricate a lead frame 298. The step-wise patterns may be etched into the die pad 302 using an etching mask or any other suitable etching technique that produces a step-wise pattern similar or identical to that shown on the die pad 302. Although only two steps 380, 382 are shown in the step-wise patterns on each side of the die pad 302, any number of steps may be etched into the die pad 302. The etching process results in the curvilinear shape of the steps 380, 382.

As previously discussed in context of FIGS. 1a and 2, because the amount of mold compound 312 present between a step 380 of the die pad 302 and a surface 316 of the package 300 is substantially greater than the amount of mold compound 112 present between surfaces 114 and 116, the mold compound 312 between the surface 316 and the step 380 is relatively stronger, stiffer and less likely to crack than the mold compound 112 between surfaces 114, 116. As such, the mold compound 312 is better able to protect the contents of the package 300 from damage. The distance indicated by arrow 352 in FIG. 3 may be application-specific and/or package-specific. Also, because the amount of mold compound 312 is gradually decreased as a center 390 of the die pad 302 is approached, the package 300 and the components comprised therein are less likely to suffer damage compared to those of FIG. 1a.

In FIG. 4, package 400 comprises a lead frame 408 and a die pad 402 having sloped outer edges 484, which may be formed by an etching process, a stamping process, or any other suitable process. Although the outer edges 484 of FIG. 4 are shown as being substantially curvilinear in shape, the outer edges 484 also may be a substantially straight surface having a non-zero angle with respect to the package surface 416, or any other suitable shape that provides a gradual decrease in the amount of mold compound abutting the die pad 402 as a center 490 of the die pad 402 is approached. The term “gradual” is intended to mean a decrease in the amount of mold compound abutting the die pad as the center of the die pad is approached that is less drastic than that shown in Figure la. A die pad that does not provide a gradual shift in the amount of mold compound abutting the die pad, as shown in FIGS. 2-4, may be susceptible to damage or the formation of cracks in the mold compound.

Although the above embodiments illustrate the step-wise interlocking feature in context of exposed-die packages, the step-wise interlocking feature may also be used in any of a variety of packages, such as quad-flat no-lead packages (“QFN”), small-outline no-lead packages (“SON”), a surface mount package, or any other suitable type of package.

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

What is claimed is:

1. A semiconductor package, comprising:
a chip;
a die pad adjacent the chip, said die pad having a side facing away from the chip, a portion of said side separated from an adjacent package surface by a distance greater than zero; and
mold compound abutting the chip and the die pad;
wherein the distance between said portion and said adjacent package surface varies.

2. The package of claim 1, wherein the portion comprises a step-wise pattern having two or more steps.

3. The package of claim 2, wherein the step-wise pattern is formed during a stamping process.

4. The package of claim 2, wherein the step-wise pattern is formed during an etching process.

5. The package of claim 2, wherein the steps are substantially equal in size.

6. The package of claim 1, wherein the portion comprises a curvilinear slope.

7. The package of claim 1, wherein the portion comprises a substantially linear slope.

8. The package of claim 1, wherein at least some of the mold compound abuts the portion.

9. The package of claim 1, wherein the package is a quad-flat, no-lead package (“QFN”).

10. The package of claim 1, wherein the package is a small-outline, no-lead package (“SON”).

11. The package of claim 1, wherein the mold compound comprises epoxy.

12. The package of claim 1, wherein the package is a surface mount package.

13. A method of preventing semiconductor die pad delamination, comprising:
forming a die pad to be mated to a package surface, said die formed to have a die pad surface, the entirety of which is not parallel to the package surface;
mating said die pad to the package surface, wherein the distance between said die pad surface and said package surface is non-zero and varies across at least a portion of said die pad; and
injecting mold compound into said package.

14. The method of claim 13, wherein forming the die pad to have the die pad surface comprises forming a non-linear surface in said die pad.

15. The method of claim 13, wherein forming the die pad to have the die pad surface comprises forming a step-wise surface in said die pad, said step-wise surface having at least 2 steps.

16. The method of claim 13, wherein forming the die pad to have the die pad surface comprises forming a curved surface in said die pad.

17. The method of claim 13, wherein forming the die pad to have the die pad surface comprises forming a linear surface in said die pad, said linear surface comprises having a non-zero angle with respect to said package surface.

18. The method of claim 13, wherein forming the die pad comprises using a stamping process.

19. The method of claim 13, wherein forming the die pad comprises using an etching process.

20. The method of claim 13, wherein using the etching process comprises using an etching mask.
